(19) United States
(12) Patent Application Publication
(10) Pub. No.: US 2006/0175630 A1
(43) Pub. Date: Aug. 10, 2006

(54) Electronic power module comprising a rubber seal and corresponding production method

(76) Inventor: Markus Meier, Rieden (DE)

Correspondence Address: HARNESS, DICKEY & PIERCE, P.L.C., P.O.BOX 8910, RESTON, VA, 20195, US

(21) Appl. No.: 10/563,054

(22) PCT Filed: May 21, 2004
(86) PCT No.: PCT/EP04/05508

§ 371 Date: Jan. 3, 2006

(30) Foreign Application Priority Data
Jul. 4, 2003 (EP) 03015213.6

(51) Int. Cl. H01L 31/111

(52) U.S. Cl. 257/177; 257/718; 257/719; 257/181; 257/E23.081

(57) ABSTRACT

An aim of an embodiment is to reduce the volume of power modules, especially for electronic motor control devices. An area is formed between cooling elements with the aid of an annular shaped rubber seal. A semi-conductor device is sealed with a sealing compound therein. Both sides of the semi-conductor device can be cooled with cooling bodies enabling the amount of space required for the power module to be reduced.

This application is the national phase under 35 U.S.C. §371 of PCT International Application No. PCT/EP2004/005508 which has an International filing date of May 21, 2004, which designated the United States of America and which claims priority on European Patent Application number 03015213.6 filed Jul. 4, 2003, the entire contents of which are hereby incorporated herein by reference.

### FIELD

The present invention generally relates to an electronic power module. In particular, it may relate to an electronic motor controller for soft-starting motors, having a first and a second cooling device and a semiconductor device which is arranged between the first and the second cooling device. The present invention also generally relates to a corresponding method for producing an electronic power module.

### BACKGROUND

An electronic power module is known as a constituent part of a power electronics unit for soft-starting motors. In this case, the power electronics unit includes one or more electronic power module or modules which has/have to be designed for short-term loading. The electronic power module is used to carry and influence current in one phase, that is to say a corresponding number of, electronic power modules are required depending on whether the network is a single-phase or three-phase network.

A power electronics unit of this type carries current only in the starting phase of the motor, the current being taken over in the operating phase by a switching device which is connected in parallel.

During the soft-starting of motors, the current is only a fraction of the direct switch-on current of the motor. During starting, the current is typically 25% to 75% of the direct switch-on current. However, soft-starting at a reduced current results in a prolonged starting time of the motor in comparison to that with direct switch-on.

Very high power losses occur in the semiconductors of the electronic power modules during the starting phase. It is necessary to ensure that the maximum permissible depletion-layer temperature for the semiconductor is not exceeded, in order to prevent the latter from being destroyed, by combining the power module or power semiconductor and a heat sink in a suitable manner. It is also necessary to minimize the space required by electronic power modules on account of the restricted space available in the switchgear cabinet.

An embodiment of a thyristor power module in which two individual thyristors are connected back-to-back in parallel and are pressed between two symmetrical heat-sink halves is known but not documented in any printed publications. One of the two heat-sink halves is divided in the middle and the two parts are connected by a flexible, electrically conductive connection. This allows the thyristor disk cells to be pressed over their surface areas, even if the disk cells are of different heights. The two heat-sink halves of this known power section, which is designed both for short-term loading and for long-term operation, are part of the electrical circuit and are therefore at a potential.

The short-term loading which occurs during soft-starting causes a very high power loss in the silicon cell, this power loss leading to the disk cell heating up immediately after loading begins. After about 2 to 5 seconds, a constant temperature difference is established between the silicon cell and the heat sink, that is to say the disk cell is in the steady state in terms of temperature, and in this state almost all of the power loss is then used to heat up the heat sink. In this case, the power section is cooled by means of a fan.

Also known are Siemens power modules from the 3RW30, 3RW22 and 3RW34 series for switching powers of less than 250 kW, these modules being made up of thyristor modules. Similarly to the above-described power modules with thyristor disk cells, these modules are cooled on one side of the thyristor by way of an aluminum heat sink. A thermally conductive paste or a thermally conductive film or foil is inserted between the thyristor module and the cooling device.

Furthermore, German patent application 100 22 341.9 from the same applicant discloses a further development of an electronic power module. This power module is distinguished in that two semiconductor components, which do not have a housing and include the actual semiconductor element and molybdenum disks, are fixed between two copper rails. This arrangement is installed and encapsulated in a housing. The encapsulation compound is used to maintain the required voltage separations and to protect the arrangement from harmful environmental influences. The heat sink is fitted to one side.

The entire structure of the abovementioned electronic power modules is relatively large, and this has a noticeably negative effect on the dimensions of the switching devices.

### SUMMARY

An object of at least one embodiment of the present invention involves reducing the dimensions of the electronic power modules while maintaining the required cooling power in the process.

According to at least one embodiment of the invention, an object may be achieved by way of an electronic power module, in particular for an electronic motor controller for soft-starting motors, having a first and a second cooling device and a semiconductor device which is arranged between the first and the second cooling device, with an elastic annular element being arranged around the semiconductor device, and with the space within the annular element, which space is partially bounded by the first and second cooling devices and in which the semiconductor device is located, being cast.

Furthermore, at least one embodiment of the invention also makes provision for a method for producing an electronic power module, in particular for an electronic motor controller for soft-starting motors, by arranging a semiconductor device between a first and a second cooling device, arranging an elastic annular element around the semiconductor device, with a space being produced within the annular element, which space is partially bounded by the first and second cooling devices and in which the semiconductor device is located, and casting the space with an encapsulation compound.

At least one embodiment of the invention is based on the idea that the conductive parts are not installed in a sealing housing, as was previously the case, and encapsulating them in this housing with a soft encapsulation compound. This design permits cooling only on one side. According to at least one embodiment of the invention however, the functions of the housing are provided by a rubber seal which is fixed between the copper rails used, for example.

The design according to at least one embodiment of the invention permits particularly low overall dimensions at simultaneously high switching frequencies. This is achieved firstly by the very low heat transfer resistance from the semiconductor, by way of heat accumulators for example, to the cooling device(s) which are fitted on both sides. However, the overall dimensions are mainly reduced in that heat is dissipated symmetrically from the semiconductors by fitting cooling device(s) on both sides.

Ideally, the overall width of the modules may be virtually halved by fitting cooling device(s) on both sides. The overall width of the switching device can be kept low because the overall width of the power module is reduced. This is highly advantageous for utilizing the volume of a switchgear cabinet to an optimum extent. A narrower overall width is more highly valued than a lower overall depth or height here.

On account of the design according to at least one embodiment of the invention, the use of complicated clamping systems, described in the abovementioned patent application, can be dispensed with, since the heat sink takes over the supporting function of the steel crossbeam or pressure apparatus used in that patent application. Cup-spring assemblies which are recessed in the heat sink may be used as the resilient element, as a result of which the overall depth can be kept low too.

Both the first and the second cooling device each preferably include at least one heat sink. Furthermore, however, the cooling devices may also each have metal rails for directly transporting heat away from the semiconductor device and for making electrical contact with the semiconductor devices.

In order to simplify assembly and to reduce production costs, the metal rails and the heat sink of a cooling device may be integrally formed. Suitable materials for this include both copper and aluminum.

The semiconductor device may have two semiconductor elements electronically connected back-to-back in parallel, in particular thyristors. In this case, the semiconductor elements are preferably in the form of semiconductor cells without a housing, so that heat can be directly transported away and a smaller physical form is possible.

The elastic annular element for sealing purposes, which element can be used to compensate for manufacturing tolerances of the cooling devices and the semiconductor elements, is preferably composed of a rubber material.

In addition to its function of mechanically protecting the semiconductors and the soft encapsulation compound, the elastic annular element has the said function of providing a liquid-tight space for the encapsulation compound by sealing off the gap between the copper rails or cooling devices. Furthermore, the elastic annular element has the function of maintaining the required minimum air gap and creepage distance between the power supply side and the load side.

Thus, the cooling devices or copper rails are at different voltage potentials and flashovers must be prevented by ensuring a predefined separation. The annular element should therefore be of a size which is substantially constant in the axial direction, so that a prespecified air gap or creepage distance is ensured between the first and the second cooling device.

Furthermore, the annular element preferably has an opening or cutout through which lines for triggering a thyristor are passed and/or through which an encapsulation compound can be introduced.

### BRIEF DESCRIPTION OF THE DRAWINGS

Embodiments of the present invention will now be explained in greater detail with reference to the attached drawings, in which:

FIG. 1 shows an exploded drawing of the parts of a power module according to at least one embodiment of the invention;

FIG. 2 shows a three-dimensional view of a fully assembled power module;

FIG. 3 shows a side view of the power module from FIG. 2;

FIG. 4 shows a cross-sectional view of the power module from FIG. 2; and

FIG. 5 shows a circuit arrangement with power modules according to at least one embodiment of the invention.

The example embodiments described in greater detail below represent preferred example embodiments of the present invention.

### DETAILED DESCRIPTION OF THE EXAMPLE EMBODIMENTS

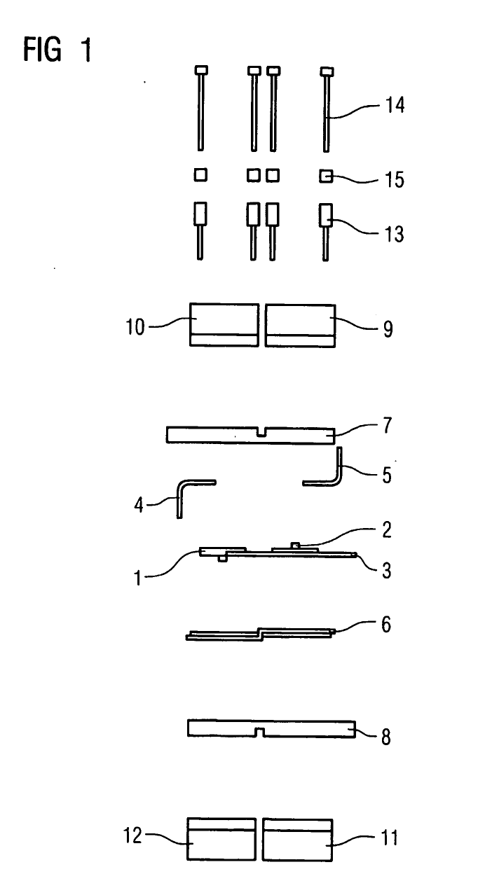

The individual components of an electronic power module according to at least one embodiment of the invention are sketched in an exploded view in FIG. 1. The central component is a semiconductor module 1. This semiconductor module includes two semiconductor cells 2 and has a gate terminal 3. Lines 4 and 5 for the auxiliary cathodes for triggering the thyristors are shown above the semiconductor module 1. In the drawing, a rubber seal 6, which surrounds the circumference of the semiconductor module 1 in the installed state, is located below the semiconductor module 1.

FIG. 1 also shows copper rails 7 and 8 which are brought into direct contact with the semiconductor module 1 in order to make contact with it and to buffer the heat lost during switching cycles. Two heat sinks 9, 10 and 11, 12 are arranged on the outer faces of each of the copper rails 7 and 8. Insulating sleeves 13, in which screws 14 are inserted, are used to secure this arrangement. Cup-spring assemblies 15 which are recessed in the respective heat sink 9, 10 are used as the resilient element. This design also serves to reduce the volume of the power module, and in particular to reduce the overall depth.

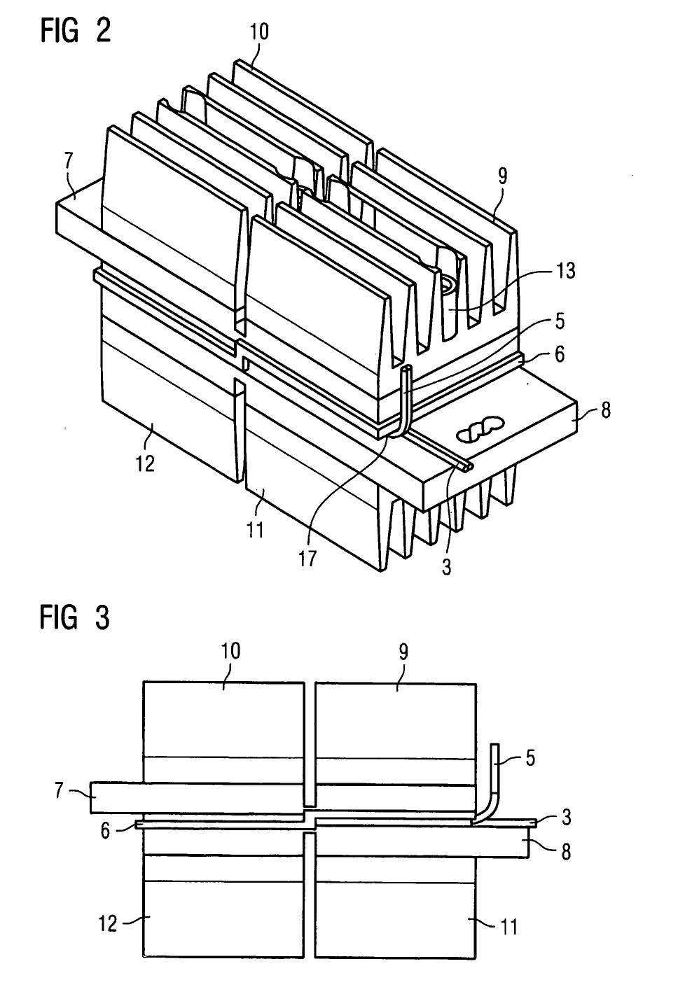

The fully assembled power module is shown in perspective in FIG. 2. Most of the elements described in connection with FIG. 1 can also be seen in this figure. However, the semiconductor module 1 cannot be seen in FIG. 2 because it is located in the space between the heat sinks 9, 10, 11 and 12 and the rubber seal 6.

A side view of the power module according to at least one embodiment of the invention is illustrated in FIG. 3. Reference is again made to FIG. 2 and FIG. 1 as regards the individual components.

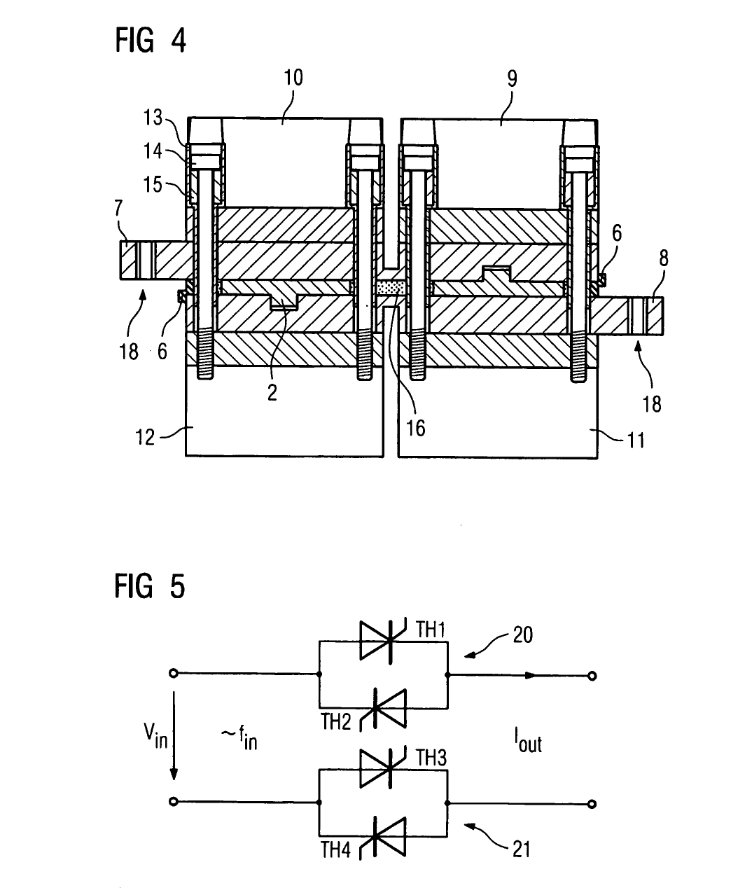

FIG. 4 shows a cross section through the side view from FIG. 3. The way in which the semiconductor cells 2 of the semiconductor module 1 are embedded in the metal or copper rails 7, 8 can be clearly seen. The copper rails 7, 8 emit their heat to the respective heat sinks 9, 10, 11 and 12. The heat sinks are usually composed of copper or aluminum. If the metal rails 7, 8 are integrally formed with the heat sinks 9, 10, 11 and 12, further heat transfer points are not needed. As a result of this, the dimensions may again be reduced and production costs may be lowered.

The semiconductor cells 2, which are shown as being integral in FIG. 4, include a silicon disk which is generally embedded between two metal disks, which are composed of molybdenum for example, and is provided with a contact-making means for applying an activation current pulse (gate line).

The space between the metal or copper rails 7, 8 and the rectangular rubber ring seal 6, in which the semiconductor module 1 or semiconductor cells 2 are located, is encapsulated with an encapsulation compound 16. The requirements in terms of stability and isolation are consequently fulfilled. To this end, FIG. 2 shows an opening 17 through which the encapsulation compound 16 can be introduced into the free space between the metal rails 7, 8 and the rubber seal 6. The connection lines 3 and 5 project through this opening 17 in the rubber seal 6.

Profiling the rubber seal 6 contributes to increasing the creepage distance between the two metal rails 7, 8 which are at different potentials. Corresponding connections 18 for making electrical contact are formed in the metal rails 7, 8.

The heat sinks 9, 10, 11 and 12 are screwed to one another by way of the screws 14, the insulating sleeves 13 and the cup-spring assemblies 15.

Finally, FIG. 5 shows an electrical circuit diagram of two power modules 20 and 21 which are connected to form a four-terminal network. Each of these power modules 20 or 21 corresponds to the power module which is illustrated in the preceding figures. The circuit diagram of each power module 20, 21 is characterized by two thyristors TH1, TH2 or TH3, TH4 electrically connected back-to-back in parallel. Each of these thyristors TH1 to TH4 is formed by a semiconductor cell 2 (cf. FIG. 1 and FIG. 4).

A voltage Vᵢₙ is applied to the input of the four-terminal network at a frequency fᵢₙ. The output current is denoted by Iₒᵤₜ.

The inventive design of the power module allows the motor to be cold-started more effectively or to be started more frequently with the power module having the same overall size, or allows the overall size of the power module to be reduced with the same cold-starting capability and starting frequency. The cold-starting capability should be understood as the maximum total load in terms of current and time which can be achieved with a motor starter, which is at a defined ambient temperature, without damaging the semiconductor switching element by exceeding the maximum permissible depletion-layer temperature. The starting frequency is to be understood as the maximum total load in terms of current and time for motor acceleration, and also the on-time and the number of switching operations per hour (cycles per unit time), which can be achieved with a motor starter, which is at a defined ambient temperature, without damaging the semiconductor switching element by exceeding the maximum permissible depletion-layer temperature.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. An electronic power module, comprising:
a first and a second cooling device;
a semiconductor device, arranged between the first and the second cooling device;
an elastic annular element, arranged around the semiconductor device, a space within the elastic annular element being encapsulated and being partially bounded by the first and second cooling devices, and the semiconductor device being located in the space.

2. The electronic power module as claimed in claim 1, wherein with the first and second cooling devices each include at least one heat sink.

3. The electronic power module as claimed in claim 1, wherein at least one of the first and second cooling device include a metal rail for directly transporting heat away from the semiconductor device and for making electrical contact with the semiconductor device.

4. The electronic power module as claimed in claim 3, wherein the respective metal rail and the at least one heat sink are integral.

5. The electronic power module as claimed in claim 3, wherein the respective metal rail and the at least one heat sink are composed of at least one of copper and aluminum.

6. The electronic power module as claimed in claim 1, wherein the semiconductor device includes two semiconductor elements electrically connected back-to-back in parallel.

7. The electronic power module as claimed in claim 6, wherein the semiconductor elements are in the form of semiconductor cells without a housing.

8. The electronic power module as claimed in claim 1, wherein the annular element is composed of rubber.

9. The electronic power module as claimed in claim 1, wherein the annular element is of a size which is substantially constant in the axial direction, so that a prespecified air gap and creepage distance are ensured between the first and second cooling devices.

10. The electronic power module as claimed in claim 1, wherein the annular element includes an opening or cutout through which at least one of lines for triggering a thyristor are passed and an encapsulation compound is introduced.

11. A method for producing an electronic power module, comprising:
arranging a semiconductor device between a first and a second cooling device;
arranging an elastic annular element around the semiconductor device, with a space being produced within the annular element, the space being partially bounded by the first and second cooling devices and the semiconductor device being located in the space; and
encapsulating the space with an encapsulation compound.

12. The method as claimed in claim 11, wherein the annular element, before encapsulation, creates a space between the two cooling devices in such a way that at least one of a prespecified air gap and creepage distance is ensured between the first and the second cooling device.

13. The electronic power module of claim 1, wherein the electronic power module is for an electronic motor controller for a soft-starting motor.

14. The electronic power module as claimed in claim 2, wherein at least one of the first and second cooling device include a metal rail for directly transporting heat away from the semiconductor device and for making electrical contact with the semiconductor device.

15. The electronic power module as claimed in claim 4, wherein the respective metal rail and the at least one heat sink are composed of at least one of copper and aluminum.

16. The method of claim 11, wherein the electronic power module is for an electronic motor controller for a soft-starting motor.
